(19) United States
(12) Patent Application Publication
(10) Pub. No.: US 2020/0180840 A1
(43) Pub. Date: Jun. 11, 2020

(54) VACUUM-PACKAGED PRODUCT OF HIGH-PURITY METAL AND METHOD FOR PRODUCING VACUUM-PACKAGED PRODUCT

(71) Applicant: JX Nippon Mining & Metals Corporation, Tokyo (JP)

(72) Inventors: Shiro TSUKAMOTO, Ibaraki (JP); Koichi TAKEMOTO, Ibaraki (JP)

(73) Assignee: JX Nippon Mining & Metals Corporation, Tokyo (JP)

(21) Appl. No.: 16/463,628

(22) PCT Filed: Mar. 6, 2018
(86) PCT No.: PCT/JP2018/008660

§ 371 Date: May 23, 2019

(30) Foreign Application Priority Data
Mar. 8, 2017 (JP) 2017-044175

(51) Int. Cl. B65D 81/20; B65D 65/42; B65B 31/00; C23C 16/06; C23C 16/40

(52) U.S. Cl. CPC B65D 81/203; B65D 65/42; C23C 16/402; C23C 16/06; C23C 16/403; B65B 31/00

(57) ABSTRACT

The purpose of the present invention is to provide a high-purity tin product not containing undesirable carbon impurities by producing a high-purity metal vacuum-packaged product (high-purity tin vacuum-packaged product) by means of vacuum-packaging of a high-purity metal (high-purity tin), wherein at least a portion of the surface of the high-purity metal is covered with dust-free paper, and the high-purity metal, at least a portion of the surface thereof being covered with the dust-free paper, is vacuum-packaged using a vacuum-packaging film.

### TECHNICAL FIELD

The present invention relates to a vacuum-packaged product of a high-purity metal and to a method for producing the vacuum-packaged product.

### BACKGROUND ART

A high-purity metal product that is desired to avoid oxidation as much as possible, such as high-purity tin product, is vacuum-packaged to prevent oxidation and contamination and then shipped. Polyethylene with lower oxygen permeability or aluminum vapor deposited polyethylene film is used as a vacuum packaging film.

The vacuum-packaged and shipped product is used after opening the package. If washing operation such as etching is carried out after opening the vacuum package, oxidation of the product will proceed with the operation. Therefore, the high-purity metal product that is desired to avoid oxidation as much as possible, such as the high-purity thin product, is shipped such that it can be immediately used as it is after opening the vacuum package. For example, the product is then immediately melted and used for subsequent precision machining.

Patent Document 1 describes an art relating to a packaged high-purity target. It discloses that when packaging the high-purity target using a polyethylene bag produced by molding polyethylene with clean air having an air cleanliness of class 6 or less, the removed target can achieve both stability at the time of initiating use in sputtering and prolonged life time characteristics.

In a so-called clean room, paper with an extremely small amount of dust generated, which is called dustless paper, is used for recording paper and the like. Polyolefin-based or polystyrene-based synthetic paper has been widely used as such dustless paper. However, it has a problem that it is difficult to use it in a heat roll fixing type printer or a copying machine, or it has a poor writing property with an aqueous pen or the like. Therefore, recently, dustless paper mainly based on pulp has been developed. The dustless paper mainly based on pulp is excellent in terms of heat resistance and writing property. Dustless paper is developed by impregnating base paper mainly based on pulp with a resin emulsion in order to prevent the generation of dusts due to falling off of pulp fibers, or the like (Patent Document

### CITATION LIST

### Patent Literatures

### Patent Document 1; Japanese Patent Application Publication No. 2001-240959 A

### Patent Document 2: Japanese Patent No. 5008127 B

### SUMMARY OF INVENTION

### Technical Problem

The present inventors was attempted to further purify high-purity tin. However, even if the further purification was advanced, heating and melting the shipped high-purity tin product often resulted in contamination of carbon impurities in the molten liquid, which caused undesirable particle formation.

It is therefore an object of the present invention to provide a high-purity tin product which does not contain undesirable carbon impurities.

### Solution to Problem

The present inventors was intensively studied to solve the above problems and tried to further purify the high-purity tin, but could not completely avoid some degree of contamination of carbon impurities. However, the present inventors has completely changed the viewpoint of research and development and then observed the surface of the high-purity tin immediately prior to heating and melting by means of an electron microscope. As a result, the present inventors have found that fine grains which are not visually observed are present, and components of the grains contain carbon when analyzed. The present inventors have then found that when vacuum-packaging high-purity tin by dustless paper interposed between a polyethylene sheet and tin, the high-purity tin product has extremely reduced carbon deposits when opening the packaging, and have completed the present invention.

Thus, the present invention includes the following aspects (1)-(19):

(1)

A vacuum-packaged product of a high-purity metal, the product comprising a vacuum-packaged high-purity metal,

wherein at least a part of a surface of the high-purity metal is covered with dustless paper; and

wherein the high-purity metal with at least a part of the surface covered with the dustless paper is vacuum-packaged by a vacuum packaging film.

(2)

The vacuum-packaged product of the high-purity metal according to (1), wherein the dustless paper has a number of particles with 0.10 μm or more of 10,000 particles/CF or less, in all of a rubbing test, a scrubbing test and a tear rubbing test, according to a dust generation test in accordance with SEMI G 67-0996.

(3)

The vacuum-packaged product of the high-purity metal according to (1) or (2), wherein the dustless paper has a thickness of from 0.01 to 0.5 mm.

(4)

The vacuum-packaged product of the high-purity metal according to any one of (1) to (3), wherein the vacuum packaging film comprises a laminated film having at least one metal vapor deposited layer or at least one metal oxide vapor deposited layer, and wherein the high-purity metal is vacuum-packaged without bringing the at least one metal vapor deposited layer or the at least one metal oxide vapor deposited layer into contact with the high-purity metal.

(5)

The vacuum-packaged product of the high-purity metal according to any one of (1) to (4), wherein the vacuum packaging film comprises a polyethylene film having at least one metal vapor deposited layer or at least one metal oxide vapor deposited layer; and wherein the high-purity metal is vacuum-packaged without bringing the at least one metal vapor deposited layer or the at least one metal oxide vapor deposited layer into contact with the high-purity metal.

(6)

The vacuum-packaged product of the high-purity metal according to any one of (1) to (5), wherein the high-purity metal has a substantially columnar, substantially rectangular parallelepiped, substantially cubic, or substantially conical shape.

(7)

The vacuum-packaged product of the high-purity metal according to any one of (1) to (6), wherein the high-purity metal has a surface roughness Ra in a range of from 0.3 to 5.0 μm.

(8)

The vacuum-packaged product of the high-purity metal according to any one of (1) to (7), wherein the high-purity metal comprises high-purity tin.

(9)

The vacuum-packaged product of the high-purity metal according to any one of (1) to (8), wherein the high-purity metal has a substantially columnar shape; wherein an entire curved surface on a side portion of the substantially columnar shaped high-purity metal is covered with the dustless paper; and wherein the substantially columnar shaped high-purity metal with the curved surface on the side portion covered with the dustless paper is vacuum-packaged by a vacuum packaging film.

(11)

A method for producing a vacuum-packaged product of a high-purity metal, the product comprising a vacuum-packaged high-purity metal, the method comprising the steps of: covering at least a part of a surface of the high-purity metal with dustless paper; and vacuum-packaging the high-purity metal with at least a part of the surface covered with the dustless paper by a vacuum packaging film,

(12)

The method for producing the vacuum-packaged product of the high-purity metal according to (11), wherein the dustless paper has a number of particles with 0.10 μm or more of 10,000 particles/CF or less, in all of a rubbing test, a scrubbing test and a tear rubbing test, according to a dust generation test in accordance with SEMI G 67-0996.

(13)

The method for producing the vacuum-packaged product of the high-purity metal according to (11) or (12), wherein the dustless paper has a thickness of from 0.01 to 0.5 mm.

(14)

The method for producing the vacuum-packaged product of the high-purity metal according to any one of (11) to (13), wherein the vacuum packaging film comprises a laminated film having at least one metal vapor deposited layer or at least one metal oxide vapor deposited layer; and wherein the high-purity metal is vacuum-packaged without bringing the at least one metal vapor deposited layer or the at least one metal oxide vapor deposited layer into contact with the high-purity metal.

(15)

The method for producing the vacuum-packaged product of the high-purity metal according to any one of (11) to (14), wherein the vacuum packaging film comprises a polyethylene film having at least one metal vapor deposited layer or at least one metal oxide vapor deposited layer; and the high-purity metal is vacuum-packaged without bringing the at least one metal vapor deposited layer or the at least one metal oxide vapor deposited layer into contact with the high-purity metal.

(16)

The method according to any one of (11) to (15), wherein the high-purity metal has a substantially columnar shape.

(17)

The method according to any one of (11) to (16), wherein the high-purity metal has a surface roughness Ra in a range of from 0.3 to 5.0 μm.

(18)

The method according to any one of (11) to (17), wherein the high-purity metal comprises high-purity tin.

(19)

The method according to any one of (11) to (18), wherein the step of covering at least a part of the surface of the high-purity metal with the dustless paper comprises covering a curved surface on a side portion of the substantially columnar shaped high-purity metal with dustless paper, and wherein the step of vacuum-packaging the high-purity metal with at least a part of the surface covered with the dustless paper by the vacuum packaging film comprises vacuum-packaging the substantially columnar shaped high-purity metal with the curved surface on the side portion covered with the dustless paper, by the vacuum packaging film.

### Advantageous Effects of Invention

According to the present invention, a high-purity metal product (a high-purity tin product) containing extremely reduced carbon impurities can be obtained. The vacuum-packaged product of the high-purity metal (the vacuum-packaged product of high-purity tin) according to the present invention can be used immediately after opening the vacuum packaging without washing or the like, for example, it can be immediately heated and melted to prepare a molten metal of the high-purity metal (tin), and can use the vacuum-packaged product of the high-purity metal according to the present invention as a molten metal for an ultrafine processing apparatus such as an LSI or the like. The molten metal has extremely reduced carbon impurities.

### BRIEF DESCRIPTION OF DRAWINGS

FIG. 1 is an SEM photograph of a surface of high-purity tin cut by a lathe.

FIG. 2-1 is an SEM image of a curved surface of a side surface of a columnar article after opening a vacuum packaged product with dustless paper according to Example 1.

FIG. 2-2 is an EDX image of a curved surface of a side surface of a columnar article after opening a vacuum packaged product with dustless paper according to Example 1.

FIG. 3-1 is an SEM image of a curved surface of a side surface of a columnar article after opening a vacuum packaged product with dustless paper according to Example 4.

FIG. 3-2 is an EDX image of a curved surface of a side surface of a columnar article after opening a vacuum packaged product with dustless paper according to Example 4.

FIG. 4-1 is an SEM image of a curved surface of a side surface of a columnar article after opening a vacuum packaged product without dustless paper according to Comparative Example 1.

FIG. 4-2 is an EDX image of a curved surface of a side surface of a columnar article after opening a vacuum packaged product without dustless paper according to Comparative Example 1.

FIG. 5-1 is an SEM image of a curved surface of a side surface of a columnar article after opening a vacuum packaged product with plain paper according to Comparative Example 2.

FIG. 5-2 is an EDX image of a curved surface of a side surface of a columnar article after opening a vacuum packaged product with plain paper according to Comparative Example 2.

FIG. 6 is an explanatory view showing positions of three straight lines assumed on a side surface of a substantially columnar sample for surface roughness measurement.

### DESCRIPTION OF EMBODIMENTS

Embodiments of the present invention will be described below in detail. The present invention is not limited to the embodiments described below.

[Method for Producing Vacuum-Packaged Product of High-Purity Metal]

The vacuum-packaged product of a high-purity metal according to the present invention can be produced by vacuum-packaging a high-purity metal using a method including the steps of covering at least a part of a surface of the high-purity metal with dustless paper; and vacuum-packaging the high-purity metal with at least a part of the surface covered with the dustless paper by a vacuum packaging film,

[High-Purity Metal]

As used herein, the high-purity metal refers to a metal having a purity of 2N (99% or more). In a preferable embodiment, the advantage of the present invention can be provided without no particular limitation as long as the purity of the high-purity metal is of such a degree that the vacuum packaging is used, and for example, metals having a purity such as 3N (99.9%), 4N (99.99%), 5N (99.999%), and 6N (99.9999%) may be used.

It should be noted that the purity of 2N or more means a purity of 99% or more, which is a purity of a high-purity metal (a percentage of the target metal contained in the high-purity metal) obtained by analyzing 73 elements other than gas component elements C, N, O, S, and H; Po, At, Fr, Ra, Ac and Pa having an extremely low abundance ratio; and artificial elements Tc and Pm, among elements of from Li to U in the periodic table, by GDMS (Glow Discharge Mass Spectrometry) method (VG-9000 from V.G. Scientific); determining the total value to be a total value of impurities assuming that the impurities are present at a detection limit value even if an amount of them is less than the detection limit value; and subtracting the total value from a total amount of the high-purity metal.

The vacuum packaging according to the present invention can be suitably used for high-purity metals that are desired to avoid oxidation as much as possible. Such high-purity metals include, for example, high purity tin (Sn), bismuth (Bi) and copper (Cu). Preferably, high-purity Sn may be used. It is important for such a high-purity metal to reduce carbon impurities, in order to use the high-purity metal as it is immediately after opening the vacuum packaging, for example to melt the high-purity metal immediately after opening the vacuum packaging, for an ultrafine processing apparatus such as an LSI or the like, without further performing washing operation such as etching, and then employ the vacuum packaged product of the high-purity metal according to the present invention as a molten metal.

[Shape of High-Purity Metal]

The shape of the high-purity metal is not particularly limited as long as it has a shape capable of carrying out the operation of vacuum packaging according to the present invention. Preferable shapes include, for example, shapes such as a substantially columnar shape, a substantially rectangular parallelepiped shape, a substantially cubic shape and a substantially conical shape. Preferably, it may be substantially columnar. A person skilled in the art would be able to perform appropriately the vacuum packaging depending on the shape of the high-purity metal, by placing the dustless paper along each shape to cover at least a part of the high-purity metal, and vacuum-packaging the high-purity metal by a vacuum packaging film.

As used herein, the ward “substantially” means almost, roughly, or nearly.

As used herein, the substantially columnar shape refers to a pillar-shaped body composed of two parallel planes with “roughly circle” and a side surface connecting these two planes, including an elliptical shape, an elliptical shape and the like, and the two parallel planes may be roughly parallel, and the plane may be roughly flat, and the pillar shaped body may be in the form of a roughly pillar body.

As used herein, the substantially rectangular parallelepiped shape refers to a hexahedron in which all surfaces are composed of “roughly rectangle”, and each surface may be roughly planar.

As used herein, the substantially cube shape refers to a hexahedron in which all surfaces are composed of “roughly square”, and each surface may be roughly planar.

As used herein, the substantially conical shape refers to a three-dimensional shape with a pointed conical shape and with a “roughly circular” bottom surface, including an elliptical shape, an elliptical shape or the like, and the bottom surface may be roughly planar, and the conical shape may be roughly conical.

[Surface Roughness of High-Purity Metal]

In a preferred embodiment, the high-purity metal may have a surface roughness Ra, for example in a range of from 0.3 to 5.0 μm, and preferably in a range of from 0.3 to 3.3 μm, and more preferably in a range of from 0.5 to 3.0 μm. In the present invention, the surface roughness Ra can be determined as an arithmetic mean roughness. The surface roughness Ra is preferably smaller from the viewpoint of reducing the amount of carbon deposited, but if the surface roughness Ra is too small, scratches will tend to be generated during subsequent work, so that the appearance will be deteriorated. In the present invention, the surface roughness Ra (center line average roughness) was obtained by assuming three parallel straight lines on a surface of a sample, measuring the surface roughness once on each of the assumed three parallel straight lines in accordance with JIS B 0601, and calculating an average value of the total three measurements. The three straight lines were assumed parallel straight lines separated from one another by 1 mm or more, each having a length of 4 mm. For example, when the sample was the substantially columnar shape having the substantially circular two planes and the side surface, it was assumed that the three straight lines were separated from one another by 1 mm to 2 mm, such that the straight lines parallel to the normal direction of the substantially circular plane are parallel to one another, on the surface of the side surface. The surface roughness can be measured using a contact surface roughness meter (Mitutoyo SJ 210).

It should be noted that the top and bottom surfaces are processed under the same conditions as those of the side surface, and, of course, the same roughness is usually obtained. Also, for the rectangular parallelepiped, cubic and conical shape, only appropriate one side is measured as a representative. Of course, the same roughness is obtained because processing is performed under the same processing conditions as described above. However, even if these surfaces do not have the same surface roughness, when the surface roughness of the part covered with the dustless paper is within the range of the surface roughness as defined above, that part will be one preferred embodiment of the present invention.

[Covering Step with Dustless Paper]

In the covering step with the dustless paper, at least a part of the surface of the high-purity metal is covered. The entire surface of the high-purity metal may be covered. In order to cover effectively the high-purity metal while maintaining the workability, a surface portion to which the vacuum packaging film is strongly pressure-bonded during the vacuum packaging is selected as at least a part of the surface to be covered, depending on the shape of the high-purity metal. For example, when the high-purity metal is substantially columnar, a curved surface on the side portion of the substantially columnar high-purity metal is covered with the dustless paper. In this case, if desired, the top surface portion and/or the bottom surface portion of the substantially columnar high-purity metal may be further covered, so that the entire surface of the substantially columnar high-purity metal may be covered.

[Dustless Paper]

The dustless paper is paper with a very small amount of dust generated. The dustless paper according to the present invention refers to dustless paper in which a number of particles having 0.10 μm or more per a cubic foot (CF) is 10000 particles/CF or less, in all of a rubbing test, a scrubbing test and a tear rubbing test, in accordance with a dust generation test according to SEMI G 67-0996. Preferably, the number of particles having 0.10 μm or more per a cubic foot may be 1000 particles/CF or less. As long as the dustless paper satisfies the above dust generation test, it is possible to use dustless paper made only of paper, dustless paper obtained by impregnating paper with a resin, dustless paper obtained by coating paper, dustless paper mainly based on materials other than paper.

In a preferred embodiment, examples of dustless paper that can be used include New Staclean® available from SAKURAI CO., LTD. or clean packaging paper available from Tanimura Corp. In a preferred embodiment, the thickness of the dustless paper may be, for example in a range of from 0.01 to 0.5 mm, preferably in a range of from 0.05 to 0.3 mm. If the thickness of the dustless paper is 0.01 mm or less, it is easy to be broken, and if it is 0.5 mm or more, it is difficult to wind it. The thickness of the dustless paper in such a range can achieve both rigidity for decreasing carbon deposits and flexibility for not breaking the vacuum packaging film during the vacuum packaging. The dustless paper easily deforms by following various shapes of high-purity metal, so that it is difficult to rub each other and it is difficult to generate dusts.

[Vacuum Packaging Film]

The vacuum packaging film that can be used includes, but not limited to, vacuum packaging films conventionally used for vacuum packaging of a high-purity metal. The vacuum packaging film to be thus used includes films with reduced oxygen permeability (oxygen barrier films) and films with reduced water vapor permeability (water vapor barrier films). Example of such vacuum packaging films include resin films having increased flexibility, laminated films having a metal layer(s) and/or a metal oxide layer (s) provided by vapor deposition or the like. Examples of resin films used for such laminated films include a polyethylene film, a nylon film, and a PET film. Examples of the metal of the metal layer provided by vapor deposition or the like include Al (aluminum) and Sn. Examples of the metal oxide of the metal oxide layer include Al₂O₃ (aluminum oxide) and SiO₂ (silicon oxide). Preferably, an Al vapor deposited polyethylene film or a Sn vapor deposited polyethylene film may be used. The vacuum packaging film that can be used may be a laminated film in which a layer(s) is/are further laminated on the above film, including, for example, laminated films in which polyethylene films, nylon films and/or PET films are further laminated on the surfaces of the metal layer and the metal oxide layer. Alternatively, a plurality of films (laminating films) can be appropriately stacked and vacuum packaging can be carried out, if desired, in order to ensure protection during transportation, or further improve the water vapor barrier property, and the like.

[Vacuum Packaging]

The vacuum packaging using the vacuum packaging film can be performed by a known means and under known conditions. In a preferred embodiment, the tin product having the above shape is covered with the dustless paper, and then placed in a packaging film formed into a bag shape, and drawn under vacuum by a compressor, and finally sealing the bag, whereby the tin product is vacuum-packaged. Examples of a usable vacuum packaging apparatus include KASHIWAGI type vacuum packaging machine (available from NPC Corporation), and GDP-400 (available from TAMURA SEAL CO., LTD.). In a preferred embodiment, the vacuum packaging can be carried out under conditions with less particles. The vacuum degree of the vacuum drawing by the vacuum packaging apparatus may be a vacuum degree which is a general packaging condition of these apparatuses, and may be, for example, in the range of from 1 to 90 kPa, and preferably from 1 to 50 kPa.

[Vacuum-Packaged Product of High-Purity Metal]

The vacuum-packaged product of the high-purity metal (the vacuum-packaged product of high-purity tin) according to the present invention can be used immediately after opening the vacuum packaging without washing or the like. For example, the vacuum-packaged product of the high-purity metal according to the present invention can be used as a molten metal for an ultrafine processing apparatus such as an LSI. The molten metal has significantly reduced carbon impurities, can suppress formation of undesirable particles, and does not generate clogging of fine flow paths.

[Microscopic Peaks and Valleys and Deposits on High-Purity Metal Surface]

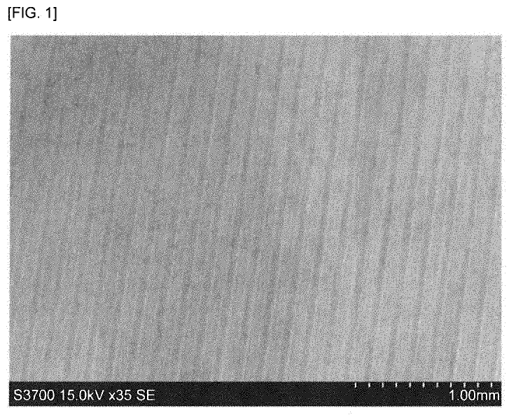

As a result of studying candidates which may be the origin of carbon deposits as observed in Comparative Examples as described below, the present inventors have concluded that the deposits have been derived from the polyethylene film adhering onto the tin surface. The surface of high purity tin is sufficiently smooth when macroscopically observed, but the surface of high purity tin forms peaks and valleys which will be derived from the cutting work and the like when microscopically observed. For example, this is as shown in the photograph of FIG. 1 which will be described below in Examples. The present inventors believe that the polyethylene film is scraped by the peaks and valleys, and fine fragments are deposited due to pressure bonding during vacuum packaging.

The microscopic peaks and valleys on the surface of high-purity tin may be probably in the form of blades, and they would be generated when the flexible polyethylene sheet is pressure-bonded onto the peaks and valleys on the tin surface and scratches the tin surface during vacuum packaging. In contrast to polyethylene, it is believed that since the paper such as dustless paper is fibrous and is not robbed at the microscopic peaks and valleys, it would not adhere to the tin surface.

### EXAMPLES

While Examples and Comparative Examples will be described below, these are merely for better understanding of the invention. The present invention is not intended to be limited by Examples or Comparative Examples.

### Example 1

Commercially available bulk tin having a purity of 4N (99.99% by mass) was prepared. It should be noted that 4N means that a purity of a high-purity metal (a percentage of the target metal contained in the high-purity metal) is 99.99%, which is obtained by analyzing 73 elements other than gas component elements C, N, O, S, and H; Pa, At. Fr, Ra, Ac and Pa having extremely low abundance ratio; and artificial elements Tc and Pm, among elements of from Li to U in the periodic table, by GDMS (Glow Discharge Mass Spectrometry) method (VG-9000 from V.G. Scientific); determining the total value to be a total value of impurities assuming that the impurities are present at a detection limit value even if an amount of them is less than the detection limit value; and subtracting the total value from a total amount of the high-purity metal.

The bulk tin was cut into a columnar shape having a diameter of 50 φmm, a length of 50 mm and a surface roughness Ra of 3.0 μm by means of a lathe.

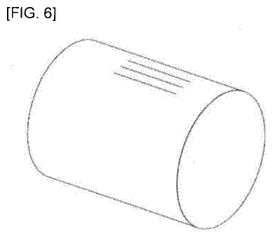

The surface roughness was measured using a contact surface roughness meter (Mitutoyo SJ 210). In the present invention, the surface roughness Ra (center line average roughness) was obtained by assuming three parallel straight lines (each length of 4 mm) parallel to the normal direction (i.e., a direction of the height of the column) of a planes corresponding to the top and bottom surfaces, on a surface of the columnar sample; such that the three straight lines were separated from one another by 1 mm to 2 mm; measuring the surface roughness once on each of the assumed three straight lines in accordance with JIS B 0601, and calculating an average value of the total three measurements. Specifically; the column of high-purity tin sample was laid down such that the central axis of the column was horizontal, and on the surface of the side surface of the column positioned on the upper side in this state, the three lines parallel to the central axis direction of the column and separated from one another by 1 mm to 2 mm were assumed and measured. These three straight lines were assumed for measurement and were not actually drawn on the surface of the sample, but an explanatory view for showing the assumed state are shown in FIG. 6.

A photograph of the surface of high-purity tin cut by the lathe as observed by SEM (scanning electron microscope) is shown as FIG. 1. FIG. 1 is a photograph of the surface of high-purity tin cut by the lathe as observed by SEM (scanning electron microscope). As shown in FIG. 1, the surface of high-purity tin appears to be smooth when macroscopically observed, but the surface forms peaks and valleys when microscopically observed. Thus, no deposition of any foreign matter is observed in the photograph of FIG. 1.

The column of tin was packaged by dustless paper New Staclearn RC (from SAKURAI CO., LTD.) having a thickness of 0.07 mm and a basis weight of 50 g/m² and further sandwiched by two Al vapor deposited polyethylene films (trade name DNP Technopack, available from Dai Nippon Printing Co., Ltd.) (a thickness of deposited Al of 12 μm, and a thickness of polyethylene of 80 μm) from the up and down directions, while directing the polyethylene surfaces to the inner side. Subsequently, the end portion was heated and sealed by a sealer to form a bag to wrap the tin, and the vacuum packaging was then carried out by heating and sealing the opening of the bag under vacuum drawing at about 50 kPa or less. The KASHIWAGI type vacuum packaging machine was used as a vacuum packaging machine. The dustless paper used in this test was prepared by impregnating long fibers with an acrylic resin, and the number of particles having 0.10 μm or more in the dust generation test according to SEMI G 67-0996 were 10 particles/CF for the rubbing test, 56 particles/CF for the scrubbing test, and 46 particles/CF for the tear rubbing tests.

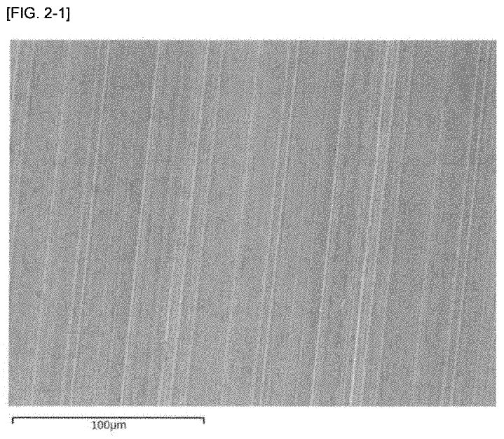

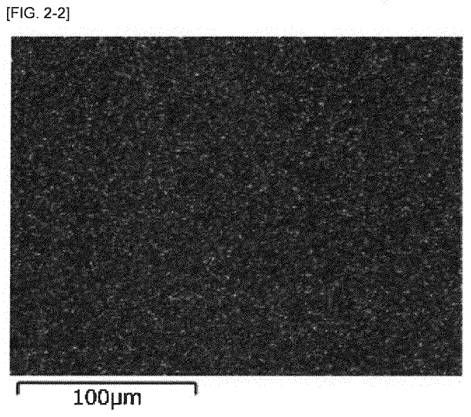

After leaving the vacuum-packaged article to stand for 3 hours, it was opened and the curved surface on the side surface of the columnar sample was observed by SEM/EDX. The results are shown in FIGS. 2-1 and 2-2.

As shown in FIGS. 2-1 and 2-2, the SEM (Scanning Electron Microscopy) and EDX (Energy Dispersive X-ray Spectroscopy) observations demonstrated that there was no deposition of carbon in the opened article of high-purity tin vacuum-packaged via the dustless paper. The observation was carried out over the entire top surface of each sample disposed for the SEM and EDX observations. The results are summarized in Table 1.

### Examples 2 and 3

Experiments were carried out by the same method as that of Example 1, with the exception that the thickness of the dustless paper in Example 1 was changed. The results were summarized in Table 1 as Example 2 (a thickness of dustless paper of 0.14 mm and a basis weight of 100 g/m²) and Example 3 (a thickness of dustless paper of 0.5 mm and a basis weight of 415 g/m²).

### Example 4

Vacuum packaging was carried out by the same method as that of Example 1 using a different grade of dustless paper EX Clean (a thickness of 0.1 mm, and a basis weight of 72 g/m²) available from SAKURAI CO., LTD. After leaving the vacuum packaged product for 3 hours, the package was opened, and the curved surface of the side surface of the columnar product was observed by SEM/EDX observations. The characteristics in the dust generation test of the dustless paper used in this test were such that the number of particles having 0.10 μm or more were 476 particles/CF for the rubbing test, 11 particles/CF for the scrubbing test, and 452 particles/CF for the tear rubbing test.

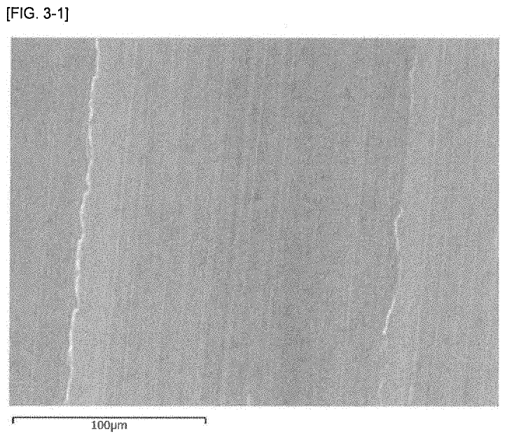

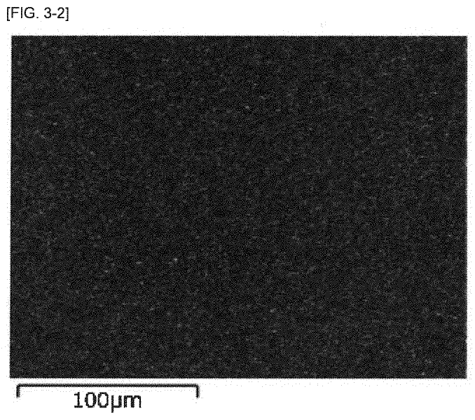

After leaving the vacuum packaged product for 3 hours, it was opened and SEM/EDX observations were performed on the curved surface of the side surface of the columnar sample. The results are shown in FIGS. 3-1 and 3-2.

As shown in FIGS. 3-1 and 3-2, the SEM (Scanning Electron Microscopy) and EDX (Energy Dispersive X-ray Spectroscopy) observations demonstrated that there was no deposition of carbon in the opened article of high-purity tin vacuum-packaged via the dustless paper. The vertical white streaks visible on the photograph are lathe eyes, and not foreign objects. The results are summarized in Table 1.

### Comparative Example 1

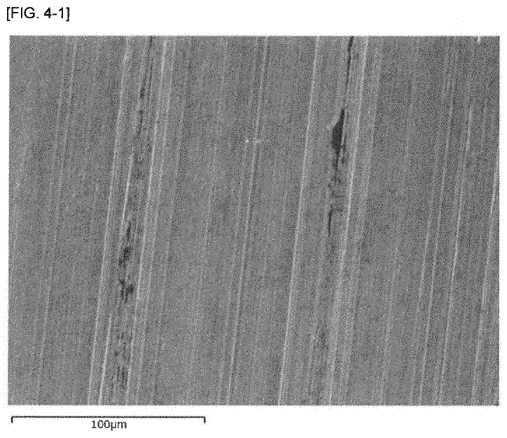

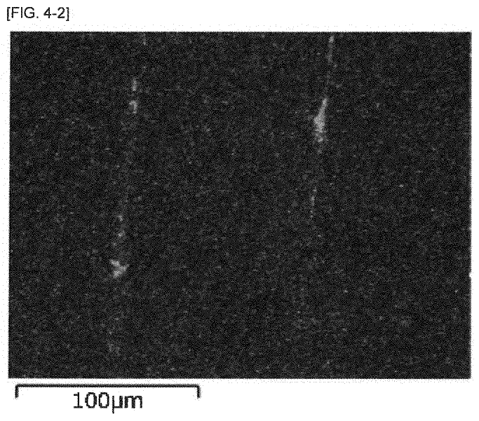

In Comparative Example 1, the vacuum packaging was carried out by the same method as that of Example 1, but without using any dustless paper, that is, directly by an Al vapor deposited polyethylene film, and the vacuum-packaged product was left to stand for 3 hours and then opened, and the curved surface on the side of the columnar sample was observed by SEM/EDX. The results are shown in FIGS. 4-1 and 4-2. Black deposits were confirmed on the SEM, and it was confirmed that they were carbon deposits as a result of EDX. These results are also summarized in Table 1.

### Comparative Example 2

A columnar sample was wrapped by an Al vapor deposited polyethylene film via plain paper (Super White Lilac available from Oji Paper Co., Ltd.) having a thickness of 0.09 mm and a basis weight of 50 g/m², rather than dustless paper, and vacuum-packaging was carried out by the same method as that of Example 1. After leaving the vacuum packaging product for 3 hours, it was opened and SEM/EDX observations were performed on the curved surface of the side surface of the columnar sample. The number of particles having 0.10 μm or more in the dust generation test of plain paper according to SEMI G 67-0996 was about 4540 particles/CF for the rubbing test, about 1362 particles/CF for the scrubbing test, and about 11722 particles/CF for the tear rubbing test.

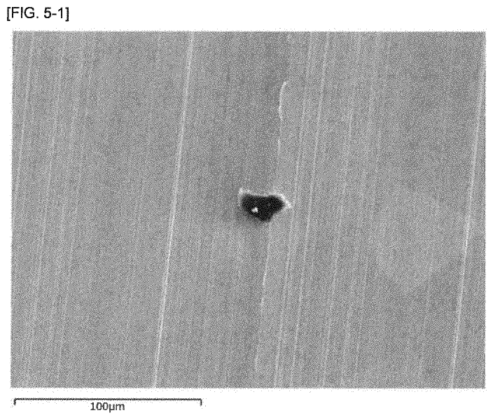

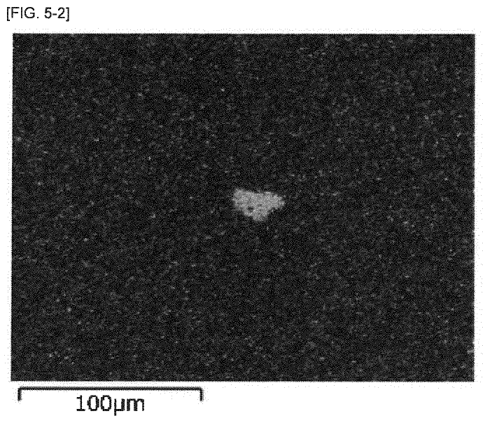

The results are shown in FIGS. 5-1 and 5-2. Many carbon-based particles were observed on the tin surface.

TABLE 1

| | | | | | Comparative | Comparative |
|---|---|---|---|---|---|---|
| | Example 1 | Example 2 | Example 3 | Example 4 | Example 1 | Example 2 |
| Presence or Absence | Present | Present | Present | Present | Absent | Absent |
| of Dustless Paper | | | | | | (Plain Paper) |
| Dustless Paper | 0.07 | 0.14 | 0.5 | 0.1 | — | 0.09 |
| Thickness (mm) | | | | | | (Plain Paper) |
| Carbon Deposition | Absent | Absent | Absent | Absent | Present | Present |
| on Tin Surface | | | | | | |

### INDUSTRIAL APPLICABILITY

According to the present invention, a high-purity metal product (a high purity tin product) containing no undesirable carbon impurities can be obtained. The present invention is an industrially useful invention.

1. A vacuum-packaged product of a high-purity metal, the product comprising a vacuum-packaged high-purity metal,
wherein at least a part of a surface of the high-purity metal is covered with dustless paper; and
wherein the high-purity metal with at least a part of the surface covered with the dustless paper is vacuum-packaged by a vacuum packaging film.

2. The vacuum-packaged product of the high-purity metal according to claim 1, wherein the dustless paper has a number of particles with 0.10 μm or more of 10,000 particles/CF or less, in all of a rubbing test, a scrubbing test and a tear rubbing test, according to a dust generation test in accordance with SEMI G 67-0996.

3. The vacuum-packaged product of the high-purity metal according to claim 1, wherein the dustless paper has a thickness of from 0.01 to 0.5 mm.

4. The vacuum-packaged product of the high-purity metal according to claim 1, wherein the vacuum packaging film comprises a laminated film having at least one metal vapor deposited layer or at least one metal oxide vapor deposited layer, and wherein the high-purity metal is vacuum-packaged without bringing the at least one metal vapor deposited layer or the at least one metal oxide vapor deposited layer into contact with the high-purity metal.

5. The vacuum-packaged product of the high-purity metal according to claim 1, wherein the vacuum packaging film comprises a polyethylene film having at least one metal vapor deposited layer or at least one metal oxide vapor deposited layer; and wherein the high-purity metal is vacuum-packaged without bringing the at least one metal vapor deposited layer or the at least one metal oxide vapor deposited layer into contact with the high-purity metal.

6. The vacuum-packaged product of the high-purity metal according to claim 1, wherein the high-purity metal has a surface roughness Ra in a range of from 0.3 to 5.0 μm.

7. The vacuum-packaged product of the high-purity metal according to claim 1, wherein the high-purity metal comprises high-purity tin.

8. A method for producing a vacuum-packaged product of a high-purity metal, the product comprising a vacuum-packaged high-purity metal, the method comprising the steps of:
covering at least a part of a surface of the high-purity metal with dustless paper; and
vacuum-packaging the high-purity metal with at least a part of the surface covered with the dustless paper by a vacuum packaging film.

9. The method for producing the vacuum-packaged product of the high-purity metal according to claim 8, wherein the vacuum packaging film comprises a laminated film having at least one metal vapor deposited layer or at least one metal oxide vapor deposited layer; and wherein the high-purity metal is vacuum-packaged without bringing the at least one metal vapor deposited layer or the at least one metal oxide vapor deposited layer into contact with the high-purity metal.

10. The method for producing the vacuum-packaged product of the high-purity metal according to claim 8, wherein the vacuum packaging film comprises a polyethylene film having at least one metal vapor deposited layer or at least one metal oxide vapor deposited layer; and the high-purity metal is vacuum-packaged without bringing the at least one metal vapor deposited layer or the at least one metal oxide vapor deposited layer into contact with the high-purity metal.
